(19) United States
(12) Patent Application Publication
(10) Pub. No.: US 2026/0266892 A1
(43) Pub. Date: Sep. 10, 2026

(54) VACUUM TEST FIXTURE FOR TESTING PRINTED CIRCUIT BOARDS

(71) Applicant: REMATEK INC., Saint-Laurent (CA)

(72) Inventors: Marco DEBLOIS, Ville St-Laurent (CA); Van Giau LUU, St-Léonard (CA); Serge AGUIAR, Sainte-Marthe-sur-le-lac (CA)

(21) Appl. No.: 19/166,177

(22) PCT Filed: Mar. 21, 2024
(86) PCT No.: PCT/CA2024/050343

§ 371 Date: Sep. 17, 2025

Related U.S. Application Data
(60) Provisional application No. 63/491,825, filed on Mar. 23, 2023.

(51) Int. Cl. G01R 31/28

(52) U.S. Cl. CPC G01R 31/2808

(57) ABSTRACT

The test fixture for testing a printed circuit board comprises a base plate for carrying bottom test probes, a top plate carried over the base plate, the top plate having a top board-bearing surface for receiving the printed circuit board, and a lid movable between an opened position away from the top plate and a closed position. The lid has a peripheral rail that engages the base plate in direct air-tight fashion in the closed position of the lid, a shell plate carried by the rail, for carrying top test probes; and a single deformable seal member disposed between the shell plate and the rail. An airtight test chamber is defined in the closed position of the lid between the base plate, the shell plate and the seal member. The shell plate and the top plate are movable relative to the base plate when a vacuum is generated in the test chamber. The shell plate and the top plate are movable in the closed position of the lid between a resting position, a first stage position where stop members stop movement of the shell plate and the top plate, and a second stage position, with respective ones of the test probes coming into contact with the circuit board in each of these positions. The seal member allows movement of the shell plate relative to the rail between the resting, the first stage and the second stage positions while also sealing an area between the shell plate and the rail for maintaining the vacuum within the test fixture, with the peripheral rail not significantly moving relative the base plate in the closed position of the lid when vacuum is generated in the test chamber such that a number of the probes contacting the printed circuit board will not change as a result of the relative position of the rail and the base plate.

### FIELD OF THE INVENTION

The present invention relates to testing devices for testing printed circuit boards, and more particularly to a vacuum-actuated test fixture for testing printed circuit boards.

### BACKGROUND OF THE INVENTION

Vacuum actuated test fixtures are used for testing printed circuit boards (PCB). Prior art test fixtures comprise a base plate having a plurality of spring-loaded electrical probes thereon, and a casing supported above the base plate and spaced away therefrom by a peripheral resiliently deformable first seal. The casing includes a perforated top plate, the undersurface of which rests against the resilient seal. A circuit board can be mounted on the top surface of the top plate. The probes of the base plate can pass through perforations of the top plate to reach the circuit board. The casing also includes a lid pivotally mounted to the upper surface of the top plate, which can be pivoted away from the top plate into an open position, and towards the top plate into a closed position. The lid comprises a peripheral lid frame and a lid plate fixedly attached to the top peripheral edge portion of the lid frame. Moreover, the lid plate comprises a number of downwardly projecting abutment fingers and in some cases test probes, both of which abut against the PCB when the lid is closed. A peripheral resiliently deformable second seal is attached to and depends downwardly from the lower rim of the lid frame, and rests against the top plate when the lid is closed.

To test a PCB with such a test fixture, the lid is opened, the PCB is mounted on the top plate using registration pins to align it properly, and the lid is closed. With the first and second seals sealing the inner chamber of the test fixture, a vacuum is created within the inner chamber, including simultaneously between the top plate and the base plate, and between the top plate and the lid. The vacuum in the test fixture's inner chamber causes the following displacements to occur concomitantly:
the lid is pulled downwardly towards the top plate, which movement is allowed by the second seal resiliently yieldingly compressing to allow the lower rim of the lid plate to move towards the top plate's upper surface. As the lid is drawn towards the top plate, the abutment fingers projecting from the lid plate are moved downwardly in order to press the circuit board against the top plate, thus securing the circuit board to the top plate. Probes mounted to the lid will also abut against the upper surface of the PCB, on specific circuit contact points of the PCB that require being verified; and
the top plate is pulled downwardly towards the base plate, which movement is allowed by the first seal resiliently yieldingly compressing to allow the top plate to move towards the base plate. As the top plate moves, probes mounted to the base plate extend through the perforations made across the top plate to abut against the undersurface of the printed circuit board to electrically connect the probes with corresponding predetermined circuit contact points of the PCB that require being verified.

Pressure applied by the probes on both sides of the circuit board, together with pressure applied by the abutment fingers, prevent the circuit board from bending or breaking. Indeed, pressure from the probes is individually modest, but pressure from all probes can amount to a very significant total force under vacuum conditions. There ca be for example a few thousands of probes below the PCB and several hundred probes above the PCB.

To ensure a reliable contact between the probes and the PCB, the probes have a spring-loaded tip, where the probe's spring will yield when the probe tip contacts the PCB. To allow a firm contact between the probes and the PCB to ensure that the testing of the circuits is accurate, the vacuum must be significant to pull down on both the top plate and the lid of the test fixture to overcome the force from the thousands of spring-loaded probe tips that abut against the circuit board.

Incidentally, one problem that relates to using such a powerful vacuum relates to its effect on the first and second seals, i.e., the deformable seal between the base plate and the top plate, and the deformable seal between the top plate and the lid. The vacuum indeed also acts on the deformable first and second seals, applying a suction force towards the interior of the test fixture's inner chamber, which means that air leaks in which compromises the vacuum inside the text fixture.

This problem is exacerbated when using so-called dual stage test fixtures. A dual stage test fixture is a test fixture that includes probes that have two different distances in the test fixture relative to the PCB, both on the base plate and on the lid. The testing occurs in two stages, namely, a first stage where only a first set of probes contact the circuit board, and a second stage where the first set of probes and a second set of probes contact the text fixture. First-stage stop members in the form of rigid non-deformable blocks are installed between the base plate and the top plate, and between the lid and the circuit board. The stop members can be moved between two positions: a first position where they will only allow the lid and top plate to move a certain distance under the effect of the vacuum such that only a first set of probes will abut against the PCB; and a second position in which they do not hinder the movement of the top plate and the lid to allow the lid and top plate to move further under the effect of the vacuum such that all probes, including the first set and a second set of probes, may contact the PCB.

With a dual stage test fixture, both the first and second deformable seals consequently need to maintain a proper sealing engagement both during the first stage when they are only partly compressed, and during the second stage when they are fully compressed. During the first stage, maintaining a proper sealing engagement is more difficult since the two seals tend to be sucked inwardly by the vacuum. While having two seals would normally require the seals to each have a lesser spring constant for purposes of deformation since it is the sum of both that allows the required deformation, however, in practice, each of these smaller seals will be weaker to resist the inward suction effect of the vacuum, especially at the first stage where both seals are not fully compressed, and this causes the text fixture to not be air-tight.

Another problem with prior art test fixtures relates to the fact that the lid must be manually opened and closed repeatedly to instal successive printed circuit boards to be tested. The problem is that when the vacuum is applied and the lid moves towards the top plate as allowed by the compression of the seal, the user's fingers might be accidentally caught between the lid and the top plate since users might act quickly under the repetitive action of testing many PCB's. With the considerable force exerted by the vacuum, this can yield to the user's fingers being crushed or cut off between the lid and the top plate.

### SUMMARY OF THE INVENTION

The invention relates to a test fixture for testing a printed circuit board, comprising:
a base plate for carrying bottom test probes;
a top plate carried over said base plate, with said bottom test probes extend through said top plate, said top plate having a top board-bearing surface for receiving the printed circuit board thereon;
a lid movable between an opened position away from said top plate for allowing access to said printed circuit board, and a closed position, said lid comprising:
   a peripheral rail that engages said base plate in direct air-tight fashion in said closed position of said lid;
   a shell plate carried by said rail, for carrying top test probes; and
   a deformable seal member disposed between said shell plate and said rail;
an airtight test chamber defined in said closed position of said lid between said base plate, said shell plate and said seal member, with said top plate being enclosed in said test chamber, said test fixture comprising at least one vacuum port in fluid connection with said test chamber for allowing a vacuum to be generated in said test chamber by a vacuum device, said shell plate and said top plate being movable relative to said base plate when a vacuum is generated within said test chamber; and
adjustable stop members, with said shell plate and said top plate being movable in said closed position of said lid between a resting position, a first stage position where said stop members stop movement of said shell plate and said top plate, and a second stage position, with respective ones of said test probes coming into contact with said circuit board in each of said resting, first stage and second stage positions;
   wherein said seal member resiliently deforms to allow movement of said shell plate relative to said rail between said resting, said first stage and said second stage positions while also sealing an area between said shell plate and said rail for maintaining the vacuum within said test fixture, with said peripheral rail not significantly moving relative said base plate in said closed position of said lid when vacuum is generated in said test chamber such that a number of said probes contacting the printed circuit board will not change as a result of the relative position of said rail and said base plate.

In one embodiment, said lid comprises at least one flange that is positioned relative to said seal member to prevent vacuum-induced deformation of said seal member towards said test chamber.

In one embodiment, said rail comprises at least one flange that is positioned relative to said seal member to prevent vacuum-induced deformation of a bottom portion of said seal member towards said test chamber, and said shell plate comprises at least one flange that is positioned relative to said seal member to prevent vacuum-induced deformation of a top portion of said seal member towards said test chamber.

In one embodiment, a sealing strip which is not significantly deformable is provided at the interface between said rail and said base plate.

In one embodiment, the test fixture further comprises springs between said rail and said shell plate for continuously biasing said shell plate away from said rail, both said seal member and said springs yielding when said shell plate moves towards either is first stage or second stage position.

In one embodiment, the test fixture further comprises an abutment plate between said shell plate and said top plate, the printed circuit board being sandwiched between said abutment plate and said top plate in said first and second stage positions of said shell plate and said top plate.

In one embodiment, the test fixture further comprises springs between said base plate and said top plate for continuously biasing said top plate towards said resting position, said springs yielding when said top plate moves towards either its first sate of second stage positions.

In one embodiment, the test fixture further comprises additional springs between said top plate and said abutment plate for continuously biasing said abutment plate away from said top plan, said additional springs yielding when the printed circuit board is sandwiched between said abutment plate and said top plate in said first and second stage positions of said shell plate and said top plate.

In one embodiment, in said rest position, no probes come into contact with said printed circuit board, in said first stage position between 1% and 99% of probes come into contact with said printed circuit board and in said second stage position 100% of probes come into contact with said printed circuit board.

### DESCRIPTION OF THE DRAWINGS

In the annexed drawings:

FIGS. 1 and 2 are front and rear perspective views of a test fixture according to the present invention, with the lid closed;

FIG. 3 is a front perspective view of the test fixture of FIGS. 1-2, which is partly broken to show inner components thereof;

FIG. 4 is an exploded partly broken front perspective view of the test fixture of FIG. 1-3, which is partly broken, and with the cover removed; and

FIGS. 5A, 5B and 5C are partial cross-sectional elevations of the test fixture of FIGS. 1-4, sequentially showing the resting position, the first stage position and the second stage position of the test fixture, respectively; with FIG. 6A further schematically showing the connection of the test probes to a computer.

### DETAILED DESCRIPTION OF THE EMBODIMENTS

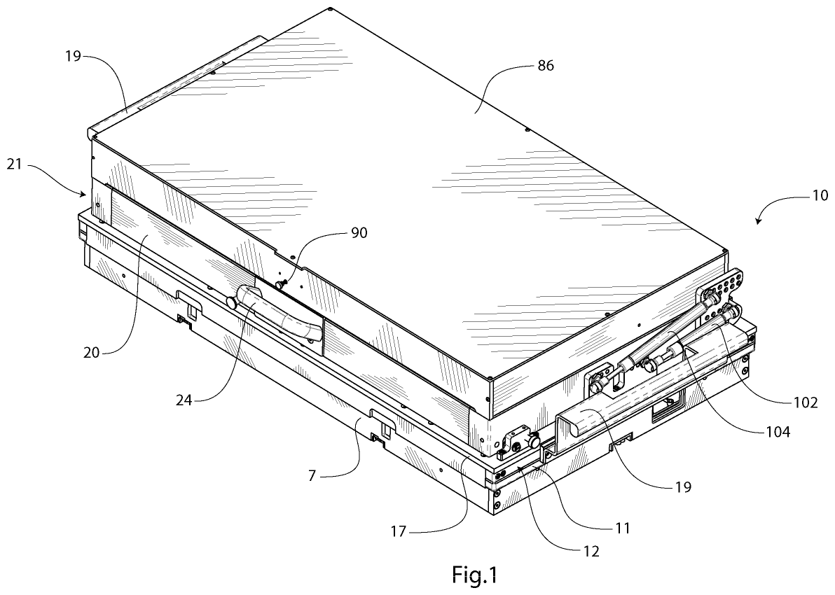

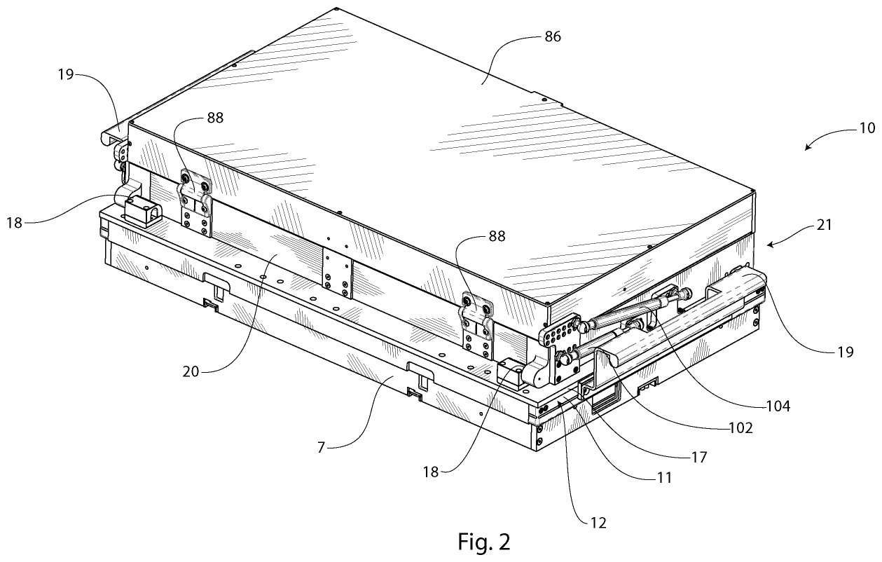

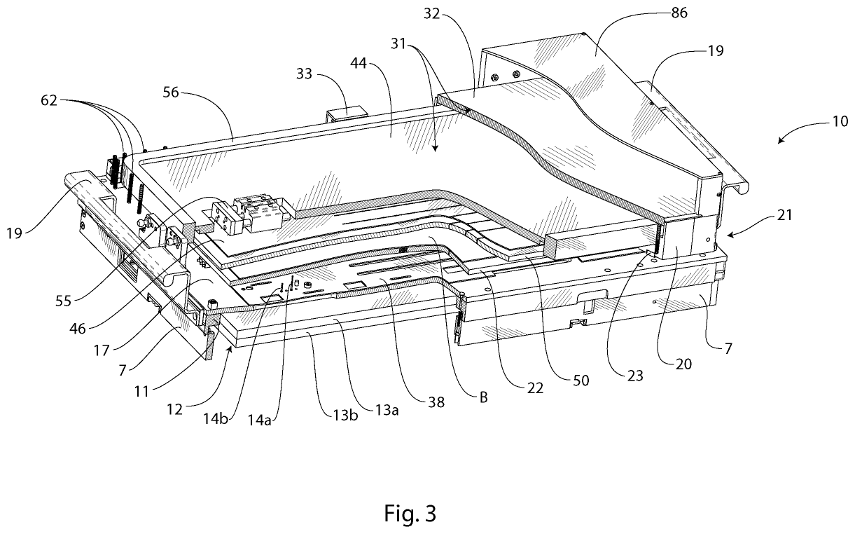

FIGS. 1-4 and 5A show a vacuum-actuated test fixture 10 for testing a printed circuit board B.

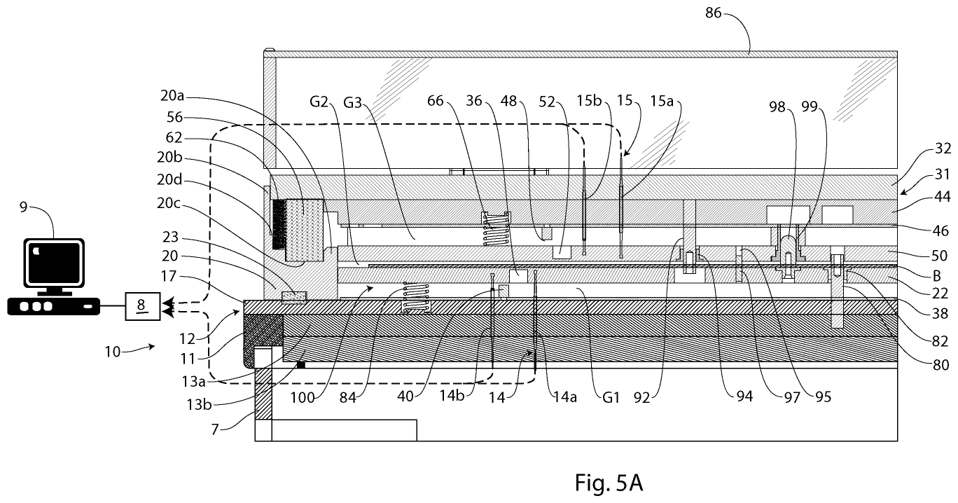

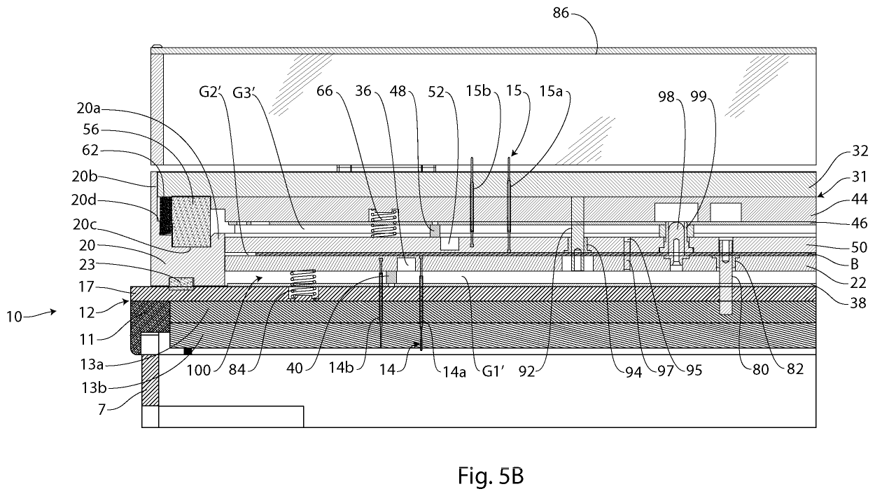

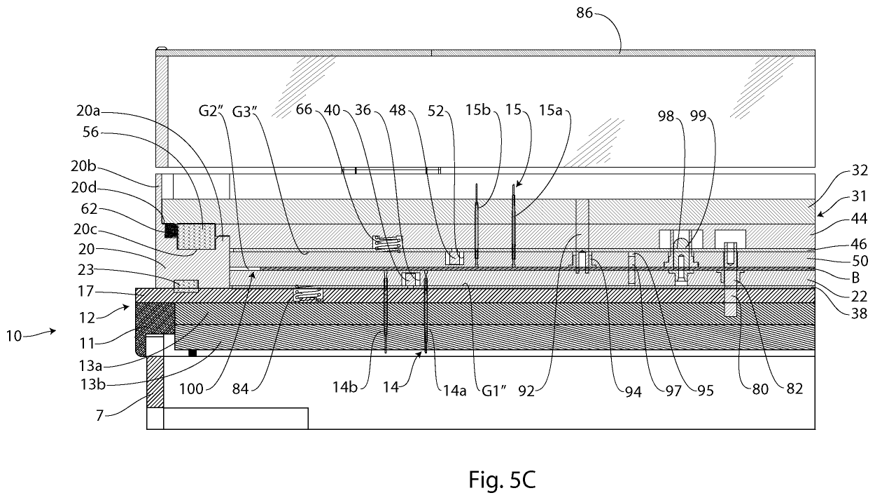

Test fixture 10 comprises a bottom frame 7 that is carried by and attached to a suitable test interface 8 that is schematically shown in FIG. 5A, as known in the art. Test interface is in turn connected to a control device in the form of a computer 9.

Test fixture 10 further comprises a base plate 12 attached to bottom frame 7. Base plate 2 carries a number of spring-loaded bottom probes 14a, 14b. Bottom probes 14a, 14b are collectively referred to as probes 14 herein. Base plate 12 comprises three plate portions 13b, 13a, 17, but could be formed of a single, two, or four or more plate portions in alternate embodiments (not shown). A base plate frame 11 is attached around base plate portions 13b, 13a, 17. Bottom probes 14 are fixed within holes made in both portions 13b, 13a, 17 of base plate 12, and the interconnection between base plate 12 and probes 14 is made airtight by a suitable sealant.

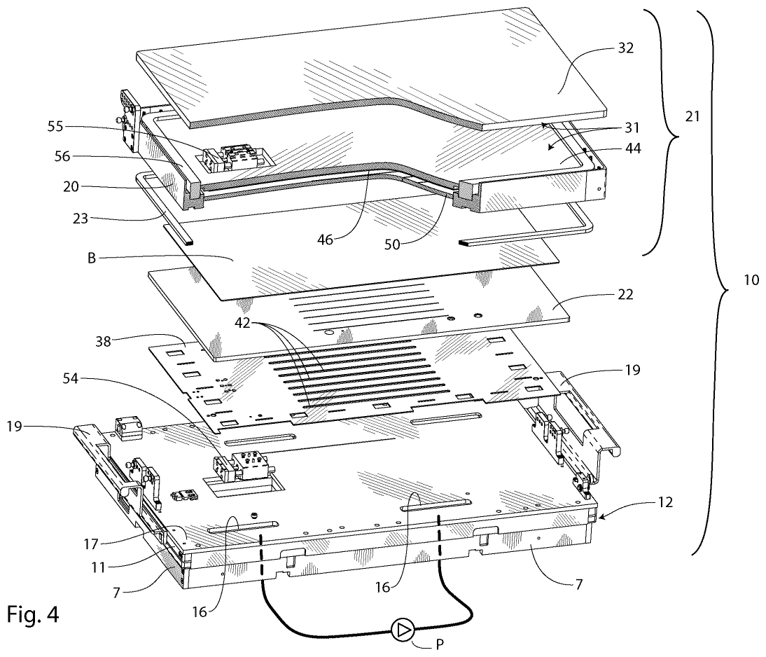

A number of vacuum ports 16 are made respectively through the topmost plate portion 17 of base plate 12, and are connected to a vacuum pump P (schematically shown in FIG. 4), to create a vacuum within test fixture 10 as detailed hereinafter.

Test fixture handles 19 attached to base plate 12 to carry test fixture 10.

A top plate 22 is attached to base plate 12, spacedly over the topmost base plate third portion 17, by means of top plate guide pins 80 that are fixedly attached to base plate 12 and that extend through bushings 82 fixed to top plate 22. Top plate coils springs 84 are installed between base plate 12 and top plate 22. Top plate 22 is vertically movable towards and away from base plate 12 as allowed by the compression of coil springs 84 and guided by the top plate guide pins 80.

A lid 21 is pivotally attached to base plate 12 by means of hinges 18. Lid 21 is pivotable relative to base plate 12 between an open position (not shown in the drawings) in which lid 21 is pivoted away from top plate 22 and in which access to top plate 22 is possible to allow installation of a circuit board B; and a closed position shown in all figures of the drawings in which lid 21 abuts atop base plate third portion 17.

Lid 21 comprises a peripheral rail 20 that is generally rectangular and hollow between the four segments that composes it. Rail 20 comprises a top a peripheral inner lip 20a and a peripheral outer lip 20b between which a peripheral groove 20c is defined. Outer lip 20b defines a peripheral shoulder 20d.

A sealing strip 23 is attached to the bottom surface of rail 20 to seal the interface between rail 20 and the top portion 17 of base plate 12 when lid 21 is in its closed position.

A handle 24 attached at a front portion of rail 20 allows a user to manipulate lid 21 to pivot it between its opened and closed positions.

Lid 21 also comprises a shell plate 31 that comprises a probe holding plate 32 which is sized to snugly fit interiorly of top flange 20b of rail 20, with its periphery extending above shoulder 20d. Probe holding plate 32 more particularly rests atop a deformable peripheral seal 56 that in turn rests within groove 20c; and atop coil springs 62 that are partly nested within rail 20 and that protrude above shoulder 20d. Probe holding plate 32 is vertically movable within the central opening of rail 20 between an upper position shown in FIG. 5A in which it abuts against retaining plates 33 (with only one being shown in the drawings, but with additional ones being provided about the periphery of rail 20), and a lower position shown in FIG. 5C in which it abuts against rail shoulder 20d. Deformable seal 56 resiliently compresses and coil springs 62 compress to allow this movement. Deformable seal 56 and coil springs 62 continuously bias probe holding plate 32 towards its upper position.

A cover 86 is pivotally attached over lid 21 by means of hinges 88. Cover may move between an opened position (not shown in the drawings) where access to probe holding plate 32 is allows and a closed position (shown in FIGS. 1, 2 and 5A, 5B, 5C) where it is pivoted against tail 20 such that the peripheral wall of cover 86 will register with the outer flange 20b of rail 20. A releasable latch 90 allows maintaining cover 86 in its closed position. Cover 86 helps avoid accidentally getting objects or a user's fingers caught in the relatively mobile portions of lid 21.

Probe holding plate 32 carries a number of spring-loaded top probes 15a, 15b that are collectively referred to as probes 15 herein. Top probes 15 extend through holes made in probe holding plate 32 and are affixed thereto, and the interconnection between probe holding plate 32 and top probes 15 is made airtight by a suitable sealant.

Probes 14, 15 are of known construction. Through the instrumentality of a suitable circuit interface such as multi-pin plug interface 8, probes 14, 15 are electrically connected to a data processor such as computer 9. Although only two top probes 15a, 15b and two bottom probes 14a, 14b are shown in the figures, it is known that a test fixture such as test fixture 10 will normally be equipped with thousands of probes 14, 15. Most often, there are more bottom probes 14 than top probes 15. For example, test fixture 10 could be equipped with 2000 bottom probes 14 and 500 top probes 15. Any suitable number of probes 14, 15 could be used, as will be obvious to a person skilled in the art.

Top plate 22 is provided with a set of bottom openings 36 that face towards base plate 12. A bottom slider plate 38 is installed atop base plate 12 and is horizontally slidable atop base plate 12. Several bottom tabs 40 (with only one bottom tab 40 and one bottom opening 36 being visible in FIGS. 5A-5C) are fixed to and upwardly project from bottom slider plate 38. Bottom slider plate 38 is horizontally movable atop base plate 12 between a first position shown in FIGS. 5A and 5B in which bottom tabs 40 are not vertically aligned with bottom openings 36 such that they may abut against the bottom surface of top plate 22 as shown in FIG. 5B; and a second position shown in FIG. 5C in which bottom tabs 40 are each vertically aligned with a corresponding bottom opening 36 such that they may engage bottom openings 36 as shown in FIG. 5C. Horizontal slots 42 are made within bottom slider plate 38 through which bottom probes 14 extend while to allow slider plate 38 to slide horizontally without probes 14 moving.

Shell plate 31 also comprises a bottom shell plate portion 44 is affixed to the bottom surface of probe holding plate 32 of lid 21. Top probes 15 extend through openings made in bottom shell plate portion 44. A top slider plate 46 is installed underneath bottom shell plate portion 44 and is horizontally slidable underneath bottom shell plate portion 44. Several top tabs 48 (with only one being shown in FIGS. 5A-5C) are fixed to and downwardly project from top slider plate 46.

An abutment plate 50 is attached to bottom shell plate portion 44, albeit spacedly from bottom shell plate portion 44, by means of guide pins 92 that downwardly depend from bottom shell plate portion 44 that engage bushings 94 provided in openings made in abutment plate 50. Abutment plate 50 snugly fits within interior lip 20a of rail 20 and is vertically movable within rail 20 towards and away from bottom shell plate portion 44, as allowed by the compression of top coil springs 66.

Abutment plate 50 is provided with a set of top openings 52 that face upwardly towards shell plate 31. Top slider plate 46 is horizontally movable under shell plate 31 between a first position shown in FIGS. 5A and 5B in which top tabs 48 are not vertically aligned with top openings 52 such that they may abut against the top surface of abutment plate 50; and a second position shown in FIG. 5C in which top tabs 48 are each vertically aligned with a corresponding bottom opening 52 such that they may engage bottom openings 36 as shown in FIG. 5C. Horizontal slots 96 are made within top slider plate 46 through which top probes 15 extend while allowing top slider plate 46 to slide horizontally without top probes 15 moving.

A bottom slider plate actuation mechanism 54 carried by base plate 12 is operatively linked to bottom slider plate 38; and a top slider plate actuation mechanism 55 carried by shell plate 31 is operatively linked to bottom slider plate 46. Top and bottom slider plate actuation mechanisms 55, 54 are capable of moving top and bottom slider plates 46, 38 between their respective first and second positions. Top and bottom slider plate actuation mechanisms 55, 54 can be any suitable mechanism capable of imparting a translation movement e.g., using a selectively powered piston.

Guide pins 98 that upwardly project from top plate 2 engage bushings 99 provided in openings made in abutment plate 50, to guide the relative movement of abutment plate 50 relative to top plate 22.

Resiliently deformable seal 56 can be made, for example, from a cross-sectionally rectangular strip of silicon-based foam or other suitable air-impermeable material. Deformable seal 56 runs continuously and is affixed within a groove 20c made on the upper surface of rail 20 and extends around the entire periphery of rectangular rail 20. The inner and outer lips 20a, 20b form flanges that flank groove 20c to provide lateral support to the bottom portion of deformable seal 56 to help avoid the bottom portion of deformable seal 56 from being inwardly deformed when under vacuum. The outer periphery of bottom shell plate portion 44, which is smaller than probe holding plate 32, also forms a flange that provides an abutment shoulder 60 to help prevent inward deformation of the upper portion of deformable seal 56 when test fixture 10 is under vacuum. Seal 56 may be fixed and sealed, e.g., with glue, both to rail 20 within groove 20c and to probe holding plate 32 to help avoid air leaks under vacuum and to also help avoid deformation of seal 56 inwardly.

An airtight test chamber 100 is consequently defined within test fixture 10, and more particularly between bottom shell plate portion 44, base plate 12 and deformable seal 56. The vacuum ports 16 are connected to test chamber 100 to enable a vacuum to be generated there with pump P.

Dampeners 102, 104 are provided between rail 20 of lid 21 and base plate 12, to avoid lid 21 from pivoting suddenly into its closed position under its own weight and possibly being damaged or injuring a user.

To test a printed circuit board B using test fixture 10, an operator pivots lid 21 into its opened position to install the circuit board B to be tested on top plate 22. Circuit board B is precisely positioned on top plate 22 with alignment pins 97 that cooperate with registration holes on circuit board B and holes 95 in abutment plate 50. Then, lid 21 is closed, such that top and abutment plates 22 and 50 are disposed on either side of printed circuit board B.

This initial or rest position of test fixture 10, where no vacuum is yet applied in test fixture 10, is shown in FIG. 5A. Circuit board B is operatively installed for testing but the testing does not yet commence since probes 14, 15 are not yet in contact with circuit board B. A first gap G1 exists between base plate 12 and top plate 22. A second smaller gap G2 exists between top plate 22 and abutment plate 50, where printed board B is installed. A third gap G3 exists between abutment plate 50 and shell plate 31.

The testing of circuit board B will commence through a command from computer 9. The testing is accomplished in two testing stages, also called two compression stages.

In the first stage of the testing, top and bottom slider plates 46, 38 are set in their first position where their tabs 48, 40 are not vertically aligned with top and bottom openings 52, 36. Vacuum pump P is activated, which leads to the pressure within test chamber 100 of test fixture 10 dropping, and a vacuum being generated therein. As shown in FIG. 5B, this will lead to:
a) The downward pull of abutment plate 50 until it abuts atop printed circuit board B. Gap G2′ between top plate 22 and abutment plate 50 diminishes and becomes equal to the thickness of circuit board B;
b) The downward pull of top plate 22 until bottom tabs 40 abut against the underside of top plate 22. Some bottom probes, namely bottom probes 14a, then come into contact with circuit board B. Gap G1′ in the first compression stage between base plate 12 and top plate 22 becomes smaller than the gap G1 in the initial position; and
c) The downward pull of shell plate 31 until top tabs 48 abut against the top surface of abutment plate 50, halting the downward movement of shell plate 31. Some top probes 15a then come into contact with circuit board B. Gap G3′ between shell plate 31 and abutment plate 50 becomes smaller than gap G3 in the initial position.

The movements described above are allowed by a combined compression of: deformable seal 56, peripheral coil springs 62 and coil springs 84, 66.

In the first stage position of test fixture 10, probes 14a and 15a may be used to test circuits of circuit board B; but not probes 14 b and 15b. Once the first stage testing is completed with probes 14a, 15a, the vacuum pump is deactivated and the vacuum within test chamber 100 of test fixture 10 is released.

In the second stage of the testing, top and bottom slider plate actuation mechanisms 55, 54 are first actuated to move top and bottom slider plates 46, 38 from their first to the second position in which top and bottom tabs 48, 40 become vertically aligned with their respective openings 52, 36. The vacuum is then reactivated within test chamber 100 of test fixture 10 with pump P. As then shown in FIG. 5C, this will lead to:
a) The downward pull of shell plate 31 until top slider plate 46 abuts against the upper surface of abutment plate 50. Top tabs 48 loosely engage top openings 52 so as not to interfere with this movement. All probes 15, including top probes 15a and top probes 15b, come into contact with circuit board B. Gap G3″ between shell plate 31 and abutment plate 50 becomes smaller than gaps G3 of the initial position and gap G3′ of the first compression stage, and is equal to the thickness of slider plate 46.
b) The downward pull of abutment plate 50 until it abuts atop printed circuit board B. Gap G2″ between top plate 22 and abutment plate 50 becomes smaller than gap G2 and is equal to the thickness of circuit board B.
c) The downward pull of top plate 22 until it abuts against the top surface of bottom slider plate 38. Bottom tabs 40 loosely engage bottom openings 36 so as not to interfere with this movement. All probes 14, including bottom probes 14a and bottom probes 14b, come into contact with circuit board B. Gap G1″ between base plate 12 and top plate 22 becomes smaller than gap G1 of the initial position and gap G1′ of the first compression stage, and is equal to the thickness of bottom slider plate 38.

In the second stage testing of test fixture 10, all probes 14, 15 are used to test circuits of circuit board B. When the second stage testing of circuit board B is finished, pump P is deactivated and the vacuum is ended within test chamber 100 of test fixture 10. The lid 21 may be opened to retrieve circuit board B and another circuit board may be installed for testing following the same steps as described above.

Coil springs 56, 84 and 66 help text fixture 10 to regain its initial position shown in FIG. 5A when vacuum is released after both the first and second stage testing shown in FIGS. 5B and 5C.

It is noted that, contrarily to prior art test fixtures that had two deformable seals, namely a first deformable seal between the top plate and the probe holding plate and a second deformable seal between the lid frame and the top plate; the test fixture 10 of the present invention instead comprises a single deformable seal 56 above rail 20, between rail 20 and probe holding plate 32. Deformable seal 56 is entirely contained within lid 21.

The sealing strip 23 might deform slightly when a vacuum is created, but this deformation is not significant, namely, it does not participate in the action of probes 14, 15 either coming into contact or being released from contact with the circuit board B. Prior art devices where a thick second deformable seal is provided under the lid are dangerous for the user: indeed, in such a case, due to the lid collapsing against the base plate under vacuum and this second seal deforming, the user's fingers can be caught between the lid and the base plate, with sufficient strength to cleanly cut the user's finger off. By providing a thin sealing strip 23 that does not participate in the actual movement of the probes against the circuit board, the initial position of lid rail 20 relative to base plate 12 is insufficient for a human finger to get caught between the lid rail 20 and the base plate, and when a vacuum is created inside test chamber 100 of test fixture 10, there is no or an insignificant movement of rail 20 towards base plate 12 under a very modest compression of sealing strip 23. This is an advantage of using a single deformable seal 56.

As such, sealing strip 23 is not considered to be significantly deformable with respect to the required and desired significant deformation of seal 56 that allows probes 14, 15 to move relative to circuit board B. Consequently, when reference to a single deformable seal 56 is made herein, this refers to an operative deformation that allows the probes 14, 15 from achieving this movement relative to circuit board B including to allow operative connection to circuit board B for testing purposes, then release from circuit board B to cease testing.

According to the present invention, the use of a single deformable seal 56 is further advantageous since it allows having a single, wider and consequently more resistant, sealing element 56 to seal the test fixture 10 between rail 20 and shell plate 31. This means that the single deformable seal 56 is less likely to deform and let air in from outside the test fixture 10 when a vacuum is being created, than in prior art devices where two weaker deformable seals are used respectively between the top plate and the probe holding plate and between the lid frame and the top plate.

The use of coil springs 62, 66, 84 helps the shell plate 31, the abutment plate 50 and the top plate 22 to move back towards their initial position shown in FIG. 5A once the vacuum is released after the first and second stage testing. It also helps seal 56 to completely resiliently recuperate its undeformed state. Also, coil springs 62 that act on shell plate 21 help apply pressure against rail 20 which, during the first and second stage compressions, and most significantly during the first stage compression while the deformable seal 56 applies less downward pressure on rail 20, helps obtain an airtight seal between rail 20 and base plate 12 with sealing strip 23.

1. A test fixture for testing a printed circuit board, comprising:
a base plate for carrying bottom test probes;
a top plate carried over said base plate, with said bottom test probes extend through said top plate, said top plate having a top board-bearing portion for receiving the printed circuit board thereon;
a lid movable between an opened position away from said top plate for allowing access to said printed circuit board, and a closed position, said lid comprising:
a peripheral rail that engages said base plate in direct air-tight fashion in said closed position of said lid;
a shell plate carried by said rail; and
a deformable seal member disposed between said shell plate and said rail;
an airtight test chamber defined in said closed position of said lid between said base plate, said shell plate and said seal member, with said top plate being enclosed in said test chamber, said test fixture comprising at least one vacuum port in fluid connection with said test chamber for allowing a vacuum to be generated in said test chamber by a vacuum device, said shell plate and said top plate being movable relative to said base plate when a vacuum is generated within said test chamber; and
adjustable stop members, with said shell plate and said top plate being movable in said closed position of said lid between a resting position, a first stage position where said stop members stop movement of said shell plate and said top plate, and a second stage position, for allowing respective ones of said test probes to come into contact with said circuit board in each of said resting, first stage and second stage positions;
wherein said seal member resiliently deforms to allow movement of said shell plate relative to said rail between said resting, said first stage and said second stage positions while also sealing an area between said shell plate and said rail for maintaining the vacuum within said test fixture, with said peripheral rail not significantly moving relative said base plate in said closed position of said lid when vacuum is generated in said test chamber.

2. A test fixture as defined in claim 1, wherein said lid comprises at least one flange that is positioned relative to said seal member to prevent vacuum-induced deformation of said seal member towards said test chamber.

3. A test fixture as defined in claim 1, wherein said rail comprises at least one flange that is positioned relative to said seal member to prevent vacuum-induced deformation of a bottom portion of said seal member towards said test chamber, and said shell plate comprises at least one flange that is positioned relative to said seal member to prevent vacuum-induced deformation of a top portion of said seal member towards said test chamber.

4. A test fixture as defined in claim 1, wherein a thin sealing strip which is not significantly deformable is provided at the interface between said rail and said base plate such that said peripheral rail does not significantly move relative to said base plate in said closed position of said lid when vacuum is generated in said test chamber, a thickness of said thin sealing strip being determined by at least one of:
the number of said probes contacting the printed circuit board not changing as a result of the relative position of said rail and said base plate; and
the distance between said rail and said base plate in said resting position not being sufficient for a user's finger to be inserted between said rail and said base plate.

5. A test fixture as defined in claim 1, further comprising springs between said rail and said shell plate for continuously biasing said shell plate away from said rail, both said seal member and said springs yielding when said shell plate moves towards either is first stage or second stage position.

6. A test fixture as defined in claim 1, further comprising an abutment plate between said shell plate and said top plate, the printed circuit board being sandwiched between said abutment plate and said top plate in said first and second stage positions of said shell plate and said top plate.

7. A test fixture as defined in claim 6, further comprising springs between said base plate and said top plate for continuously biasing said top plate towards said resting position, said springs yielding when said top plate moves towards either its first sate of second stage positions.

8. A test fixture as defined in claim 7, further comprising additional springs between said shell plate and said abutment plate for continuously biasing said abutment plate away from said shell plate, said additional springs yielding when the printed circuit board is sandwiched between said abutment plate and said top plate in said first and second stage positions of said shell plate and said top plate.

9. A test fixture as defined in claim 1, wherein said rest position is configured for allowing no probes to come into contact with said printed circuit board, while said first stage position is configured for allowing between 1% and 99% of said probes to come into contact with said printed circuit board and said second stage position is configured for allowing 100% of said probes to come into contact with said printed circuit board.

10. A test fixture as defined in claim 1, wherein said board-bearing portion of said top plate comprises a board-bearing surface for flat abutment of said top plate against the printed circuit board, and wherein said test fixture further comprises a number of bottom probes carried by said base plate and a number of top test probes carried by said shell plate, each of said top probes for coming into contact with the printed circuit board in one or more of said resting, said first stage and second stage positions.

11. A test fixture for testing a printed circuit board, comprising:
a base plate for carrying bottom test probes;
a top plate carried over said base plate, with said bottom test probes extend through said top plate, said top plate having a top board-bearing portion for receiving the printed circuit board thereon;
a lid movable between an opened position away from said top plate for allowing access to said printed circuit board, and a closed position, said lid comprising:
a peripheral rail that engages said base plate in direct air-tight fashion in said closed position of said lid;
a shell plate carried by said rail; and
a deformable seal member disposed between said shell plate and said rail; and
an airtight test chamber defined in said closed position of said lid between said base plate, said shell plate and said seal member, with said top plate being enclosed in said test chamber, said test fixture comprising at least one vacuum port in fluid connection with said test chamber for allowing a vacuum to be generated in said test chamber by a vacuum device, said shell plate and said top plate being movable relative to said base plate when a vacuum is generated within said test chamber;
wherein said shell plate and said top plate are both movable in said closed position of said lid between a resting position and a contacting position, for allowing said bottom test probes to come into contact with said circuit board at least in said contacting position; and wherein said seal member resiliently deforms to allow movement of said shell plate relative to said rail between said resting and said contacting positions while also sealing an area between said shell plate and said rail for maintaining the vacuum within said test fixture, with said peripheral rail not significantly moving relative said base plate in said closed position of said lid when vacuum is generated in said test chamber.

12. A test fixture as defined in claim 11, wherein said lid comprises at least one flange that is positioned relative to said seal member to prevent vacuum-induced deformation of said seal member towards said test chamber.

13. A test fixture as defined in claim 11, wherein said rail comprises at least one flange that is positioned relative to said seal member to prevent vacuum-induced deformation of a bottom portion of said seal member towards said test chamber, and said shell plate comprises at least one flange that is positioned relative to said seal member to prevent vacuum-induced deformation of a top portion of said seal member towards said test chamber.

14. A test fixture as defined in claim 11, wherein a thin sealing strip which is not significantly deformable is provided at the interface between said rail and said base plate such that said peripheral rail does not significantly move relative to said base plate in said closed position of said lid when vacuum is generated in said test chamber, a thickness of said thin sealing strip being determined by at least one of:
the number of said probes contacting the printed circuit board not changing as a result of the relative position of said rail and said base plate; and
the distance between said rail and said base plate in said resting position not being sufficient for a user's finger to be inserted between said rail and said base plate.

15. A test fixture as defined in claim 11, further comprising springs between said rail and said shell plate for continuously biasing said shell plate away from said rail, both said seal member and said springs yielding when said shell plate moves towards said contacting position.

16. A test fixture as defined in claim 11, further comprising an abutment plate between said shell plate and said top plate, the printed circuit board being sandwiched between said abutment plate and said top plate in said contacting position of said shell plate and said top plate.

17. A test fixture as defined in claim 16, further comprising springs between said base plate and said top plate for continuously biasing said top plate towards said resting position, said springs yielding when said top plate moves towards said contacting position.

18. A test fixture as defined in claim 17, further comprising additional springs between said shell plate and said abutment plate for continuously biasing said abutment plate away from said shell plate, said additional springs yielding when the printed circuit board is sandwiched between said abutment plate and said top plate in said contacting position of said shell plate and said top plate.

19. A test fixture as defined in claim 11, wherein said rest position is configured for allowing no probes to come into contact with said printed circuit board, while said contact position is configured for allowing 100% of probes come into contact with said printed circuit board.

20. A test fixture as defined in claim 11, wherein said board-bearing portion of said top plate comprises a board-bearing surface for flat abutment of said top plate against the printed circuit board, and wherein said test fixture further comprises a number of bottom probes carried by said base plate and a number of top test probes carried by said shell plate for coming into contact with the printed circuit board at least in said contacting position.

21. A method of testing a printed circuit board in a test fixture, the test fixture comprising a base plate for carrying bottom test probes, a top plate carried over said base plate, with said bottom test probes extending through said top plate, said top plate having a top board-bearing portion for receiving the printed circuit board thereon, a lid movable between an opened position away from said top plate for allowing access to said printed circuit board, and a closed position, a shell plate carried by said rail, and a deformable seal member disposed between said shell plate and said rail, said method comprising the steps of:
closing the lid against the base plate such that an airtight test chamber is formed between said base plate, said shell plate and said seal member, with said top plate being entirely enclosed in said test chamber, said lid comprising a peripheral rail that engages said base plate in direct air-tight fashion when said lid is closed;
generating a vacuum in said test chamber through at least one vacuum port that is in fluid connection with said test chamber with a vacuum device;
said shell plate and said top plate both moving relative to said base plate under the action of the vacuum generated within said test chamber;
said deformable seal member deforming to allow this movement of said shell plate and top plate; and
said peripheral rail not significantly moving relative to said base plate in said closed position of said lid when vacuum is generated in said test chamber.

22. The method as defined in claim 21, wherein the step of said peripheral rail not significantly moving relative to said base plate in said closed position of said lid when vacuum is generated in said test chamber is accomplished by providing a thin sealing strip which is not significantly deformable at the interface between said rail and said base plate, a thickness of said thin sealing strip being determined by at least one of:
the number of said probes contacting the printed circuit board not changing as a result of the relative position of said rail and said base plate; and
the distance between said rail and said base plate in said resting position not being sufficient for a user's finger to be inserted between said rail and said base plate.
